(19) United States
(12) Patent Application Publication
(10) Pub. No.: US 2003/0075807 A1
(43) Pub. Date: Apr. 24, 2003

(54) Interconnect structure with a cap layer on an IMD layer and a method of formation thereof

(76) Inventors: Chen-Chiu Hsue, Hsinchu (TW); Shyh-Dar Lee, Hsinchu Hsien (TW); Jen-Hann Tsai, Tainan (TW)

Correspondence Address: BIRCH STEWART KOLASCH & BIRCH, PO BOX 747, FALLS CHURCH, VA, 22040-0747, US

(21) Appl. No.: 10/153,808

(22) Filed: May 24, 2002

(30) Foreign Application Priority Data
Oct. 24, 2001 (TW) 90126264

(51) Int. Cl. H01L 23/48

(52) U.S. Cl. 257/774

(57) ABSTRACT

An interconnect structure comprises a first level metal wiring line patterned on a semiconductor substrate, an inter-metal dielectric (IMD) layer formed on the metal wiring line, a contact plug passing through the IMD layer and electrically connected to the top of the first level metal wiring line, and a second level metal wiring line patterned on the IMD layer and electrically connected to the top of the contact plug. A cap layer is sandwiched between the top of the IMD layer and the bottom of the second level metal wiring line.

### BACKGROUND OF THE INVENTION

1. Field of the Invention

The present invention relates to an interconnect structure in semiconductor and, more particularly, to an interconnect structure with a cap layer on an inter-metal dielectric (IMD) layer and a method of formation thereof.

2. Description of the Related Art

In a typical integrated circuit, various devices and components are insulated by an isolation structure. To electrically connect certain parts of the devices or components, an interconnect structure is commonly used, conventionally formed by patterning a plurality of metal wiring lines and then applying an inter-metal dielectric (IMD) layer to isolate them. In order to achieve a satisfactorily planarized surface, chemical-mechanical polishing (CMP) is employed to planarize the top of the IMD layer or the so-called sacrificial layer to facilitate the fabrication of the next metal wiring layer.

FIGS. 1A to 1D are cross-sectional diagrams showing a conventional method of forming an interconnect structure. As shown in FIG. 1A, a semiconductor substrate 10 comprises a plurality of first level metal wiring lines 12, a first oxide layer 14 formed on the metal wiring lines 12, and a second oxide layer 1G formed on the first oxide layer 14. The first oxide layer 14 may be formed by high density plasma chemical vapor deposition (HDPCVD) or plasma enhanced chemical vapor deposition (PECVD) to fill the gaps between metal wiring lines 12. The second oxide layer 16, preferably formed by PECVD, serves as a sacrificial layer to provide thickness to the subsequent CMP. As shown in FIG. 1B, using the CMP, part of the second oxide layer 16 is polished away to obtain a planarized surface. The remaining parts of the first oxide layer 14 and the second oxide layer 16 combine to serve as an IMD layer 18 for isolating interconnect structures.

Referring to FIG. 1C, using a patterned photoresist layer 19 as a mask, the IMD layer 18 is anisotropically etched to form a plurality of via holes 20 and expose the top of each of the metal wiring lines 12. As shown in FIG. 1D, after removing the patterned photoresist layer 19, a conductive layer is deposited on the IMD layer 18 to fill the via holes 20. Using photolithography and etching, the conductive layer positioned on the IMD layer 18 is patterned to become a plurality of second level metal wiring lines 24. The remaining part of the conductive layer within each via hole 20 serves as a contact plug 22 for electrically connecting the second level metal wiring line 24 to the first level metal wiring line 12. Thus, the second level metal wiring line 24, the contact plug 22, and the first level metal wiring line 12 form a vertically stacked interconnect structure.

However, poor adhesion found between the metal wiring line 24 and the IMD layer 18 must be overcome. The outgassing effect of the IMD layer 18 is another important issue, causing metal wiring line 24 to peel from the IMD layer 18, especially when organic low-k dielectric materials are applied to the use of the IMD layer 18. These problems decrease the stability of the interconnect structure, and reduce throughput. Thus, a cap layer for encapsulating the IMD layer from the surrounding metal wiring lines and enhancing the adhesion between the metal wiring lines and the IMD layer is called for.

### SUMMARY OF THE INVENTION

The present invention provides an interconnect structure with a cap layer sandwiched between the top of an IMD layer and the bottom of a metal wiring line to solve the above-mentioned problems. The present invention also provides a method of forming the interconnect structure with the cap layer on the IMD layer.

The interconnect structure comprises a first level metal wiring line patterned on a semiconductor substrate, an inter-metal dielectric (IMD) layer formed on the metal wiring line, a contact plug passing through the IMD layer and electrically connected to the top of the first level metal wiring line, and a second level metal wiring line patterned on the IMD layer and electrically connected to the top of the contact plug. A cap layer is sandwiched between the top of the IMD layer and the bottom of the second level metal wiring line.

The IMD layer is silicon oxide formed by chemical vapor deposition (CVD). Preferably, the IMD layer comprises a first oxide layer formed on the first level metal wiring line by high density plasma chemical vapor deposition (HDPCVD), and a second oxide layer formed on the first oxide layer by plasma enhanced chemical vapor deposition (PECVD). Alternatively, the IMD layer is of organic low-k dielectric materials formed by spin coating. The IMD layer provides a planarized surface before the formation of the cap layer. The cap layer may be of inorganic based materials such as SiON, SiO₂, SiC, SiN and other materials with low dielectric constant, or organic-based materials.

In the method of forming the interconnect structure, the semiconductor substrate is provided with the first level metal wiring line and the IMD layer covering the first level metal wiring line. Then, the surface of the IMD layer is planarized by CMP. Next, the cap layer is formed on the planarized surface of the IMD layer. Next, a via hole is formed to pass through the cap layer and the IMD layer to expose the top of the first level metal wiring line. By depositing a conductive layer on the cap layer to fill the via hole, the contact plug is formed within the via hole. Finally, patterning the conductive layer over the contact plug, the second level metal wiring line is formed on the contact plug. Thus, the remaining part of the cap layer is sandwiched between the top of the IMD layer and the bottom of the second level metal wiring line.

Accordingly, it is a principle object of the invention to provide a cap layer for improving adhesion between the IMD layer and the second level metal wiring line.

It is another object of the invention to provide a cap layer for preventing the second level metal wiring line from peeling.

Yet another object of the invention is to provide a cap layer to solve the outgassing problem of the IMD layer.

It is a further object of the invention to ensure the reliability of the interconnect structure.

Still another object of the invention is to simplify the process and improve throughput.

These and other objects of the present invention will become readily apparent upon further review of the following specification and drawings.

### BRIEF DESCRIPTION OF THE DRAWINGS

FIGS. 1A to 1D are cross-sectional diagrams showing a conventional method of forming an interconnect structure.

FIGS. 2A to 2F are cross-sectional diagrams showing a method of fabricating an interconnect structure according to the present invention.

FIGS. 3 is a cross-sectional diagram showing another preferred embodiment of the interconnect structure according to the present invention.

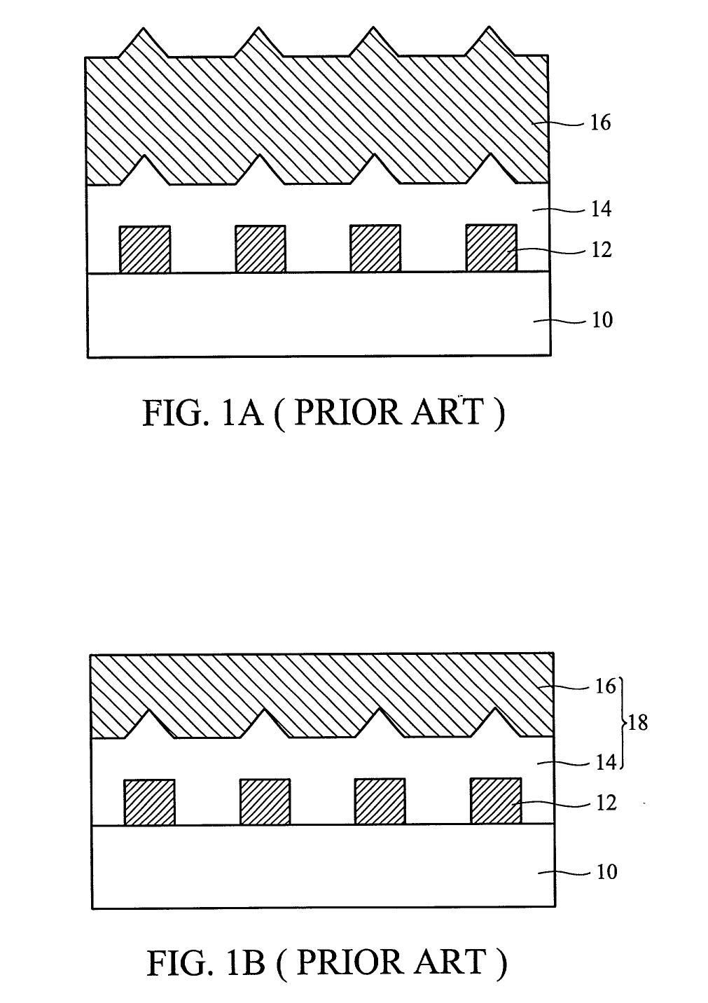

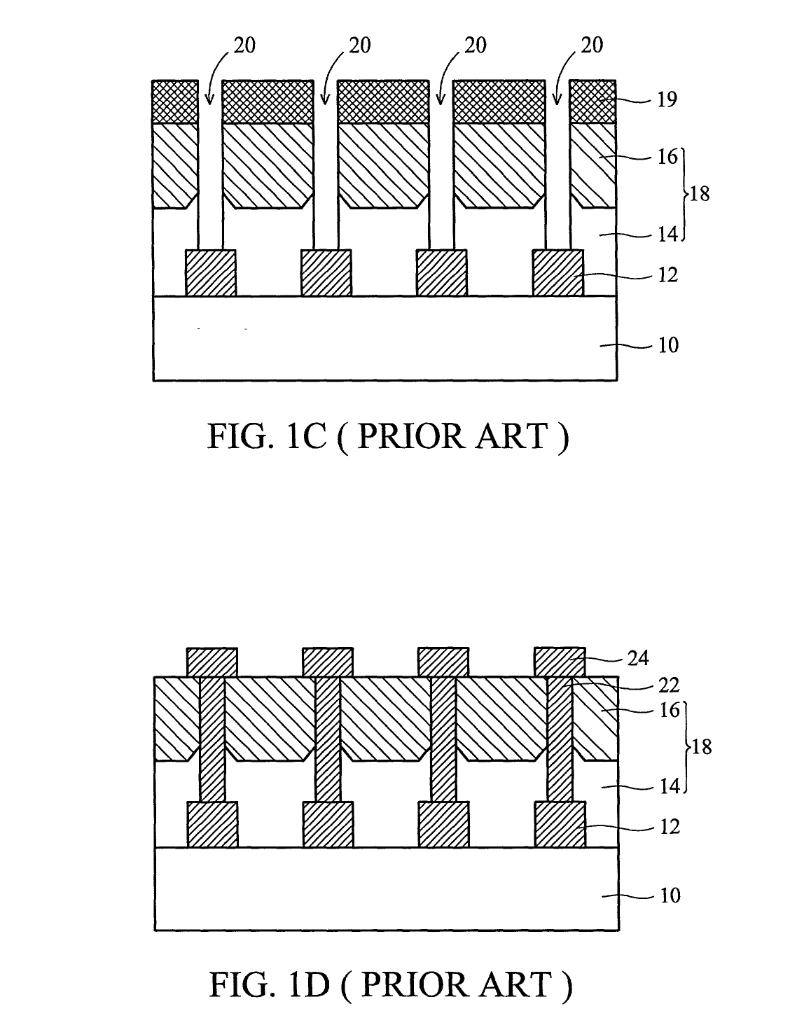

Similar reference characters denote corresponding features consistently throughout the attached drawings.

### DETAILED DESCRIPTION OF THE PREFERRED EMBODIMENTS

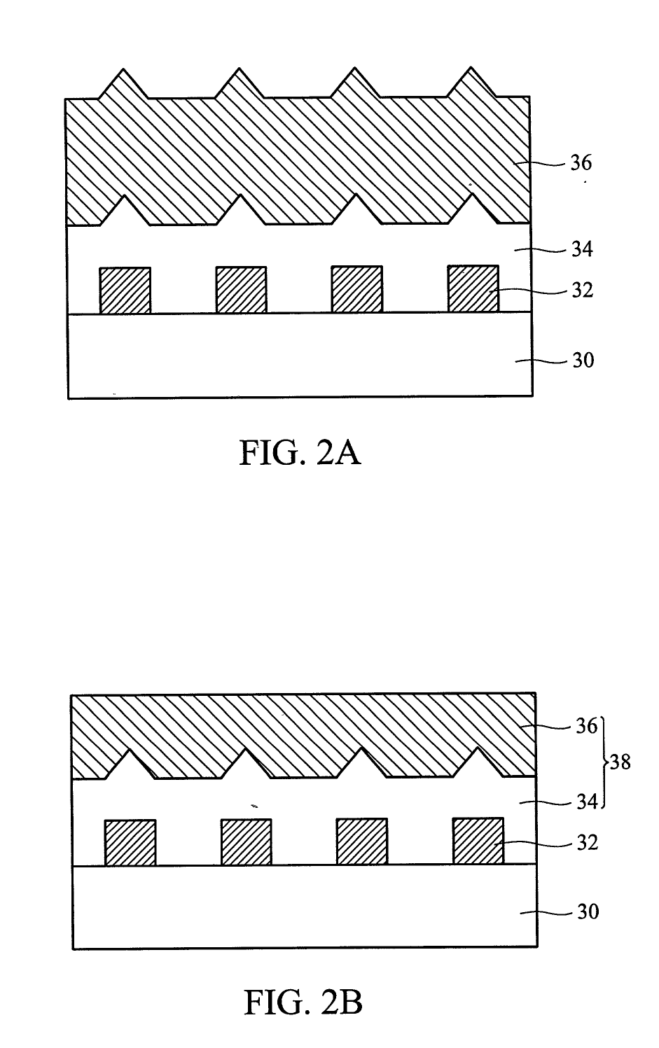

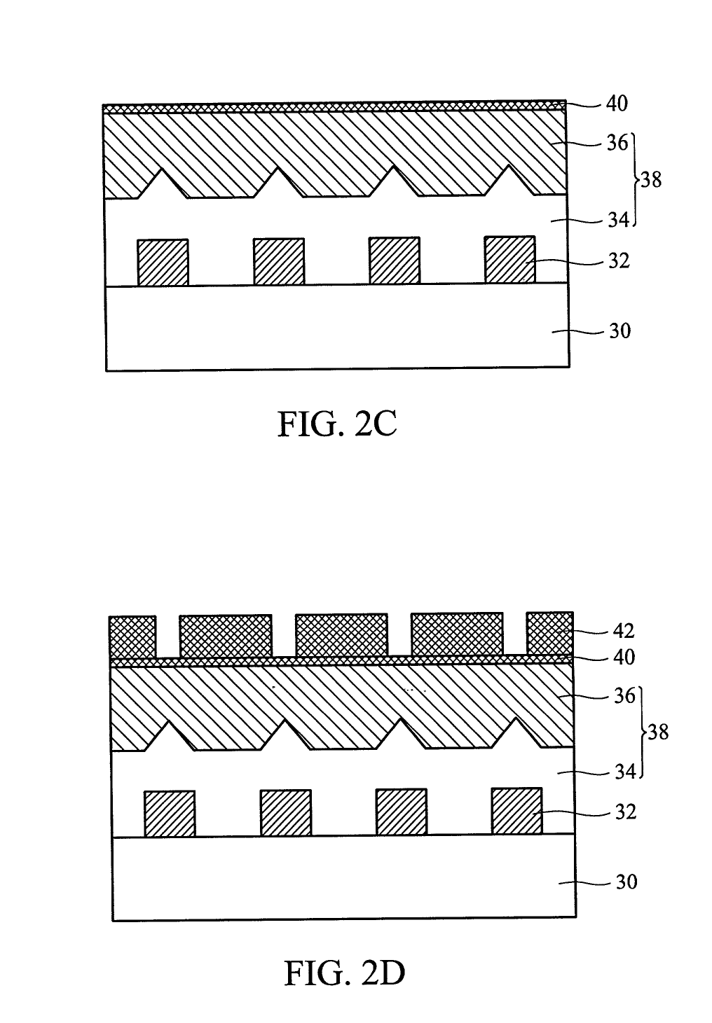

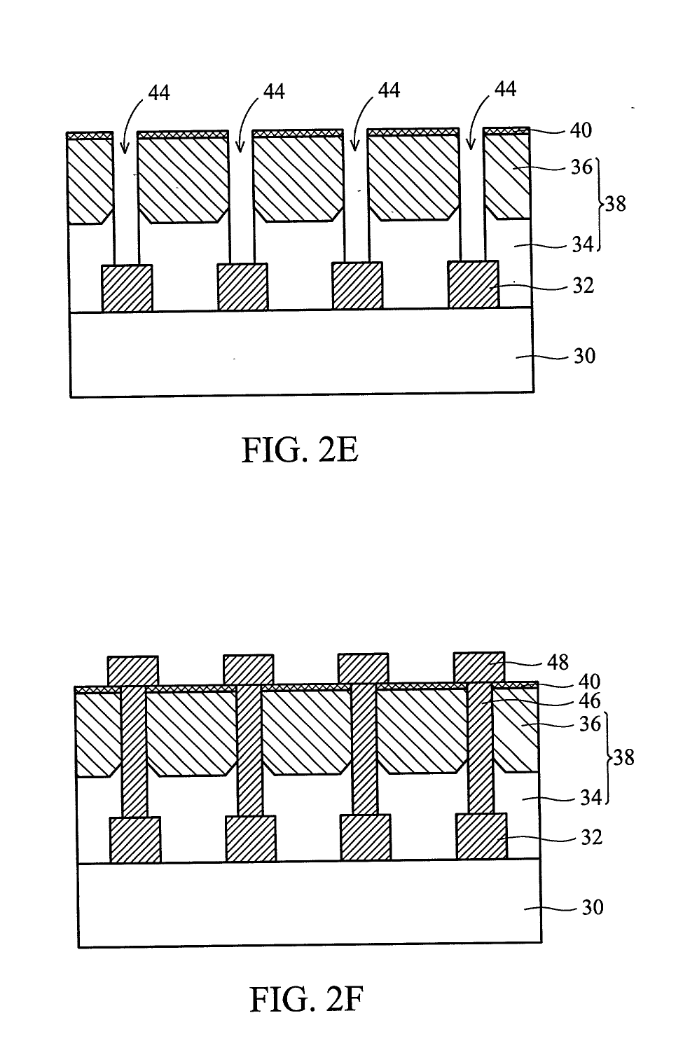

FIGS. 2A to 2F are cross-sectional diagrams showing a method of fabricating an interconnect structure according to the present invention. As shown in FIG. 2A, a semiconductor substrate 30 is provided, possibly containing, for example, transistors, diodes, other semiconductor elements as well known in the art, or other metal interconnect layers. First, using deposition, photolithography and etching, a plurality of metal wiring lines 32 are patterned on the semiconductor substrate 30. The metal wiring lines 32, serving as the first level interconnect structure, may be formed from a variety of materials, such as aluminum, aluminum alloyed with silicon or copper, copper alloys, and multilayer structures. In one preferred embodiment, the metal wiring line 32 has a multilayer structure, with a first Ti layer, a first TiN layer, an AlCu layer, a second Ti layer, and a second TiN layer.

Then, using high density plasma chemical vapor deposition (HDPCVD), a first oxide layer 34 with a low dielectric constant (low-k) is formed on the metal wiring lines 32 to completely fill the gaps between them. Since the HDPCVD may accomplish both deposition and etching at the same time, a taper topography of the first oxide layer 34 is produced over the metal wiring lines 32. Alternatively, plasma-enhanced chemical vapor deposition (PECVD) is used to form the first oxide layer 34. Next, using plasma enhanced chemical vapor deposition (PECVD), a second oxide layer 36 with a low dielectric constant (low-k) is deposited on the entire surface of the first oxide layer 48 to a predetermined thickness. The top surface of the second oxide layer 36 appears a corresponding topography. The second oxide layer 36 presents as a sacrificial layer for providing thickness to the subsequent CMP processes.

Referring to FIG. 2B, the CMP is performed to planarize the top of the second oxide layer 36, therefore a planarization layer is provided for the subsequent contact plug. The remaining part of the first oxide layer 34 and the second oxide layer 36 surrounding the metal wiring lines 32 serve as an IMD layer 38. Referring to FIG. 2C, a cap layer 40 is formed on the IMD layer 38. The formation of the cap layer 40 may employ inorganic based materials via chemical vapor deposition (CVD) or organic based materials via spin-on coating. The inorganic based materials maybe SiON, SiO₂, SiC, SiN, or other materials with a low dielectric constant (k<4). The organic based materials may be chromophone. The cap layer 40 which encapsulates the IMD layer 38 from the subsequently formed metal wiring lines can enhance the adhesion between them and reduce the outgassing effect of the IMD layer 38.

Referring to FIGS. 2D and 2E, using a patterned photoresist layer 42 as a mask and consecutively etching the cap layer 38, the second oxide layer 36 and the first oxide layer 34 from exposed regions by anisotropic etching, such as reactive ionized etcher (RIE), the IMD layer 38 is patterned to become a plurality of via holes 44 and expose the top of each of the metal wiring lines 32. Then, the patterned photoresist layer 42 is removed. It is noticed that the cap layer 40, of SION, SiO2, SiC, or SiN, serves as a quarter wave plate during the exposure of the photoresist layer 42 in order to prevent light from passing through the cap layer 40 and prevent light from reflecting back up to the photoresist layer 42. This can allow the critical dimensions of the via holes 44 to be scaled down in the next generation of SC process.

Referring to FIG. 2F, a conductive layer which may be formed from a variety of materials, such as aluminum, aluminum alloyed with silicon or copper, copper alloys is deposited on the cap layer 40 and fills the via holes 42. Using photolithography and etching with the cap layer 40 as an etch stopper, the conductive layer is patterned as a plurality of metal wiring lines 48 to serve as the second level interconnect structure. The remaining parts of the conductive layer within the via holes 44 serve as contact plugs 46 for electrically connecting the second level metal wiring lines 48 to the first level metal wiring lines 32 respectively. Thus, the second level metal wiring line 48, the contact plug 46, and the first level metal wiring line 32 form a vertically stacking interconnect structure. Note that methods of fabricating the contact plug 46 and metal wiring lines 48 are design choices dependent on the fabrication methods employed in the overall process.

According to this method of forming the interconnect structure, the present invention provides the cap layer 40 sandwiched between the top of the IMD layer 38 and the bottom of the second level metal wiring line 48 to improve adhesion between and prevent the metal wiring line 48 from peeling. In addition, the cap layer 40 solves the outgassing problem of the IMD layer 38. This ensures the reliability of the interconnect structure. Furthermore, the cap layer 40 serves as an anti-reflective coating during the exposure of the photoresist layer 42, and serves as an etch stopper during the formation of the second level metal wiring lines 48. This simplifies the and promotes the throughput.

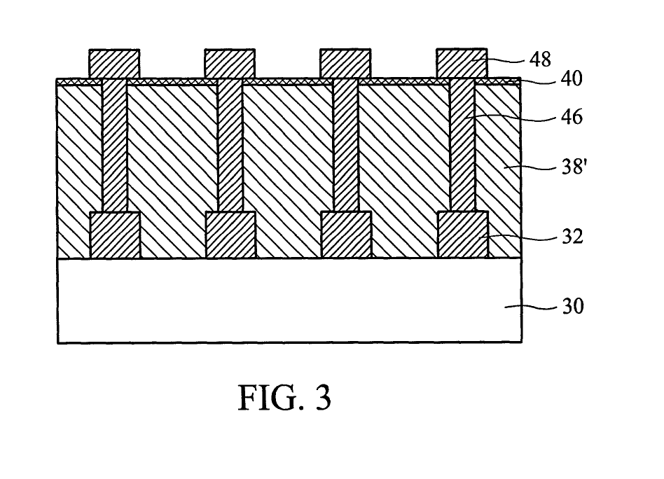

In addition, organic low-k dielectric materials can substitute the first oxide layer 34 and the second oxide layer 36. Referring to FIG. 3, an IMD layer 38′ of organic low-k dielectric materials may be selected from spin-on glass (SOG), spin-on polymer (SOP), such as FLARE, SILK, Parylene, or PAE-II, and formed through spin-coating. This further simplifies the and lowers the production cost.

It is to be understood that the present invention is not limited to the embodiments described above, but encompasses any and all embodiments within the scope of the following claims.

What is claimed is:

1. An interconnect structure, comprising:
a first level metal wiring line patterned on a semiconductor substrate;
an inter-metal dielectric (IMD) layer formed on the metal wiring line;
a contact plug passing through the IMD layer and electrically connected to the top of the first level metal wiring line;
a second level metal wiring line patterned on the IMD layer and electrically connected to the top of the contact plug; and
a cap layer sandwiched between the top of the IMD layer and the bottom of the second level metal wiring line.

2. The interconnect structure according to claim 1, wherein the cap layer is of inorganic based materials comprising SiON, SiO₂, SiC, SiN and other materials with a low dielectric constant.

3. The interconnect structure according to claim 1, wherein the cap layer is of organic based materials.

4. The interconnect structure according to claim 1, wherein the IMD layer is of silicon oxide formed by chemical vapor deposition (CVD).

5. The interconnect structure according to claim 4, wherein the IMD layer comprises:
a first oxide layer formed on the first level metal wiring line by high density plasma chemical vapor deposition (HDPCVD); and
a second oxide layer formed on the first oxide layer by plasma enhanced chemical vapor deposition (PECVD).

6. The interconnect structure according to claim 1, wherein the IMD layer is of organic low-k dielectric materials formed by spin coating.

7. The interconnect structure according to claim 1, wherein the IMD layer provides a planarized surface.

8. A method of fabricating an interconnect structure, comprising steps of:
providing a semiconductor substrate which has a first level metal wiring line and an inter-metal dielectric (IMD) layer covering the first level metal wiring line;
planarizing the surface of the IMD layer;
forming a cap layer on the planarized surface of the IMD layer;
forming a via hole passing through the cap layer and the IMD layer to expose the top of the first level metal wiring line;
filling the via hole with a contact plug; and
forming a second level metal wiring line on the contact plug;
wherein the remaining part of the cap layer is sandwiched between the top of the IMD layer and the bottom of the second level metal wiring line.

9. The method according to claim 8, wherein the cap layer is of inorganic based materials such as SiON, SiO2, SiC, SiN and other materials with a low dielectric constant formed by chemical vapor deposition (CVD).

10. The method according to claim 8, wherein the cap layer is of organic based materials formed by spin coating.

11. The method according to claim 8, wherein the IMD layer is of silicon oxide by chemical vapor deposition (CVD).

12. The method according to claim 11, wherein the formation of the IMD layer comprises steps of:
forming a first oxide layer on the first level metal wiring line by high density plasma chemical vapor deposition (HDPCVD) and
forming a second oxide layer on the first oxide layer by plasma enhanced chemical vapor deposition (PECVD).

13. The method according to claim 8, wherein the IMD layer is of organic low-k dielectric materials formed by spin coating.
